(19) United States
(12) Patent Application Publication
(10) Pub. No.: US 2026/0147961 A1
(43) Pub. Date: May 28, 2026

(54) METHOD, RECORDING MEDIUM, AND SYSTEM FOR AUTOMATICALLY DESIGNING CUSTOMIZED ROBOT USING AI AGENT

(71) Applicant: Vision Space, Seoul (KR)

(72) Inventor: Wonseok Choi, Seongnam-si (KR)

(73) Assignee: Vision Space, Seoul (KR)

(21) Appl. No.: 18/963,312

(22) Filed: Nov. 27, 2024

(30) Foreign Application Priority Data
Nov. 26, 2024 (KR) 10-2024-0170916

(51) Int. Cl. G06F 30/27

(52) U.S. Cl. CPC G06F 30/27

(57) ABSTRACT

A method for automatically designing customized robot using an AI agent, includes: acquiring user requirements for a customized robot, processing the user requirements, including at least two data types selected from textual descriptions, images, and 3D models, generating a customized robot design based on the processed user requirements, optimizing the robot design using machine learning techniques and a knowledge base of robotics principles, validating the optimized robot design using simulation tools, and assisting in the construction and deployment of the robot.

### CROSS-REFERENCE TO RELATED APPLICATION

This application claims the benefit of priority to Korean Patent Application No. 10-2024-0170916, filed Nov. 26, 2024, the aforementioned priority application being hereby incorporated by reference in its entirety.

### TECHNICAL FIELD

This disclosure relates to the field of robotics and artificial intelligence, particularly to methods for automatically designing customized robots using AI agents that leverage multimodal data and machine learning techniques.

### BACKGROUD

Designing and building robots is a complex and time-consuming process. Traditionally, it involves significant human expertise and manual effort to design the robot's structure, select appropriate components, and ensure the robot meets specific task requirements. This process can be inefficient and costly, especially when customized robot solutions are needed for diverse applications.

### BRIEF DESCRIPTION OF THE DRAWINGS

FIG. 1A shows a schematic diagram of a process for automatically generating a customized robot using an AI agent.

FIG. 1B shows a diagram illustrating a configuration for evaluating the generation of a customized robot using an AI agent.

FIG. 2A shows a schematic diagram for collecting robot skill data for automatically generating a customized robot using an AI agent.

FIG. 2B shows a diagram illustrating a configuration for evaluating the performance of a robot skill data set for automatically generating a customized robot using an AI agent.

FIG. 3A shows a schematic diagram illustrating a digital twin industry and robot simulation.

FIG. 3B shows a schematic diagram for accelerating the collection of data for automatically generating a customized robot using an AI agent.

FIG. 4 shows a diagram illustrating a configuration for accelerating the collection of a robot learning data set and a robot skill set.

### DETAILED DESCRIPTION

This disclosure introduces a method for automatically designing customized robots using AI agents. This addresses the limitations of traditional robot design processes, which are often manual, time-consuming, and require significant expertise. By leveraging AI agents capable of processing multimodal data and utilizing machine learning techniques, this method enables efficient and customized robot design, making advanced robotics technology more accessible.

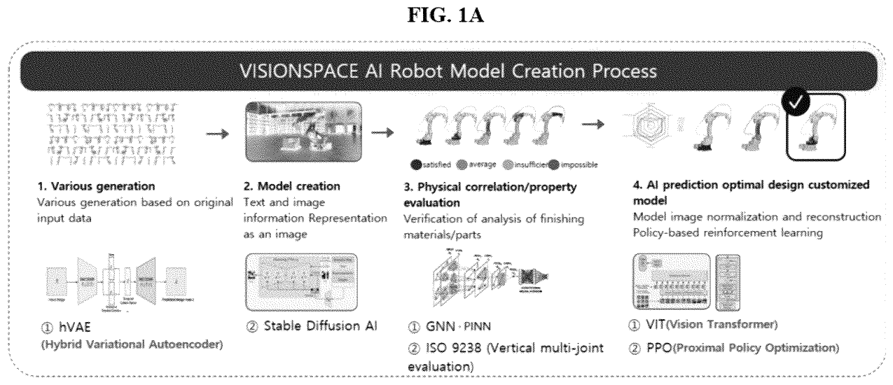

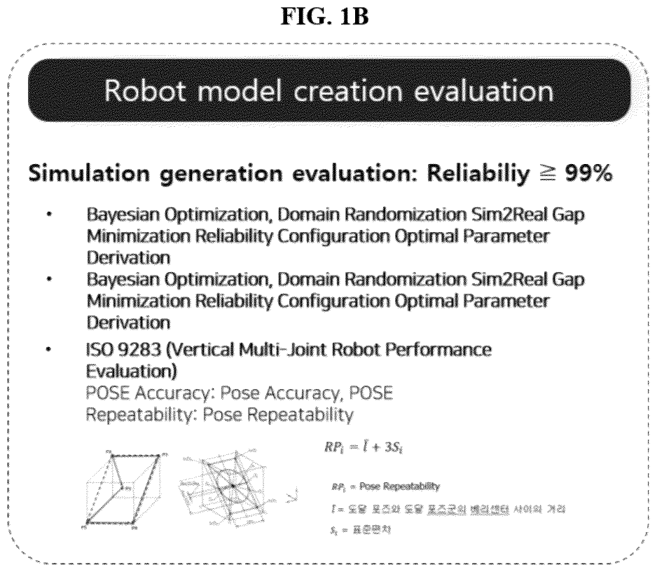

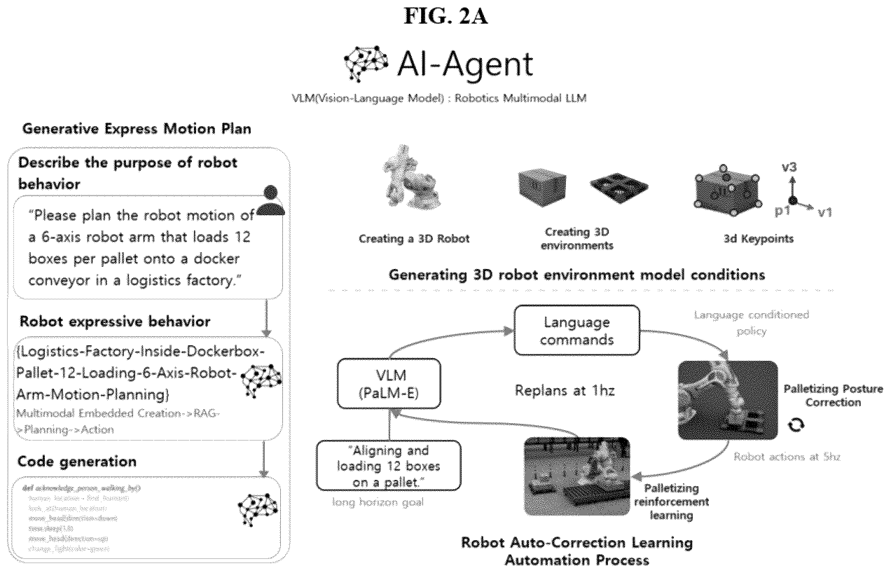

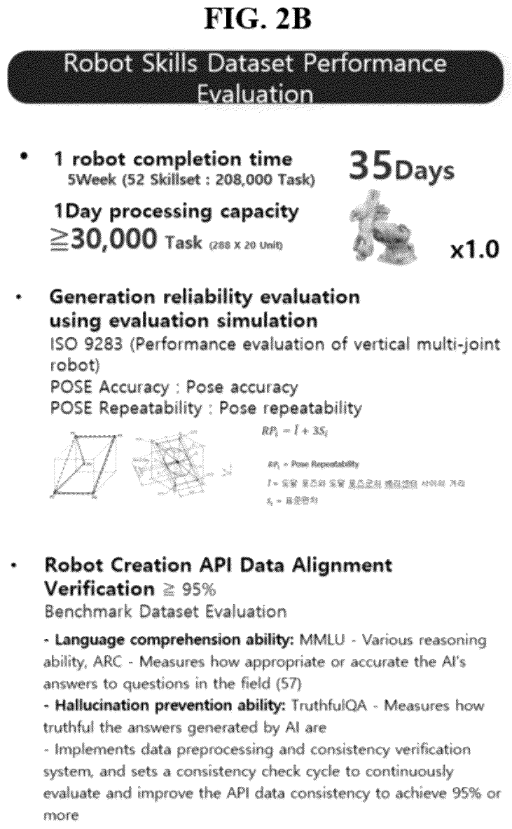

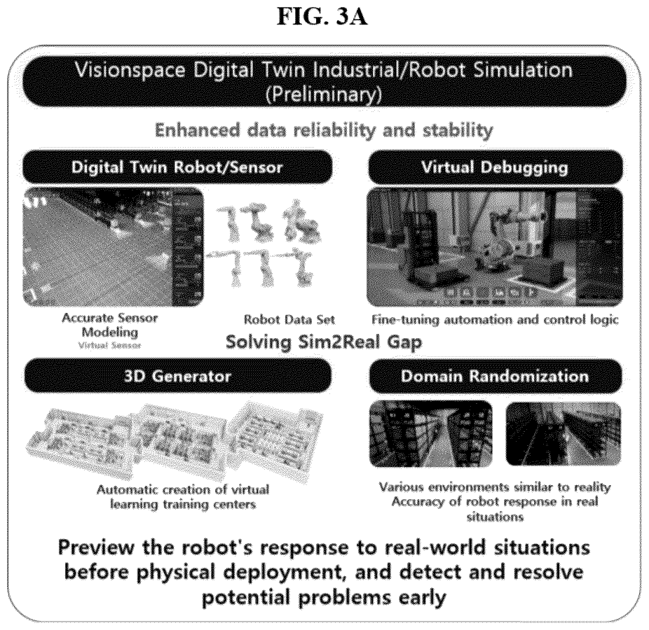

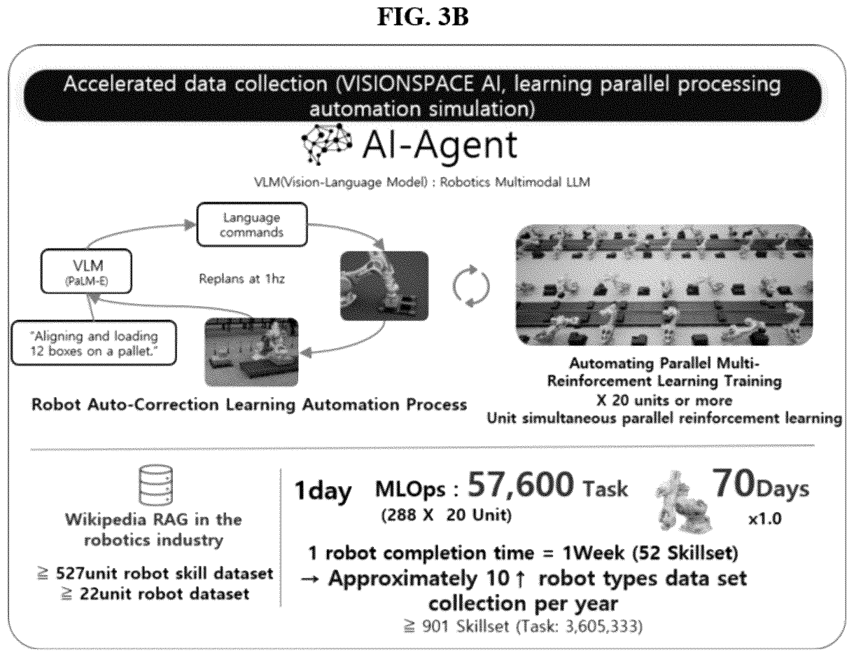

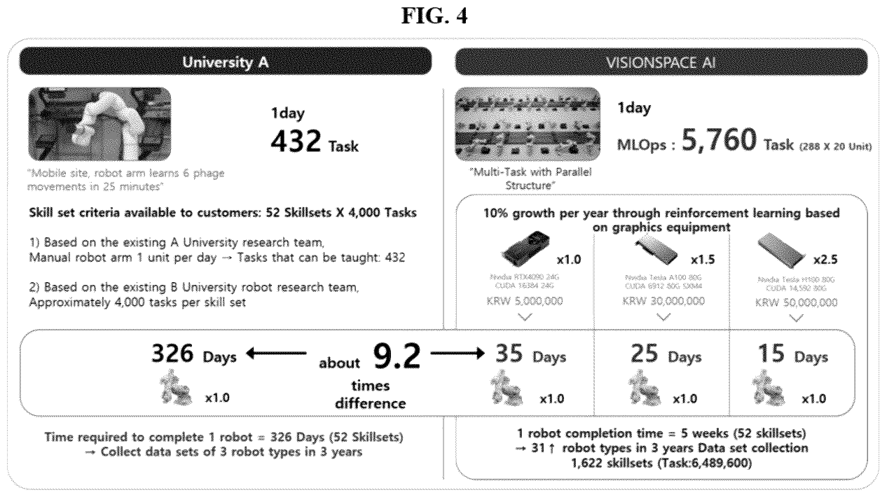

Hereinafter, FIG. 1A shows a schematic diagram of a process for automatically generating a customized robot using an AI agent, and FIG. 1B shows a diagram illustrating a configuration for evaluating the generation of a customized robot using an AI agent. Further, FIG. 2A shows a schematic diagram for collecting robot skill data for automatically generating a customized robot using an AI agent, and FIG. 2B shows a diagram illustrating a configuration for evaluating the performance of a robot skill data set for automatically generating a customized robot using an AI agent. Furthermore, FIG. 3A shows a schematic diagram illustrating a digital twin industry and robot simulation, and FIG. 3B shows a schematic diagram for accelerating the collection of data for automatically generating a customized robot using an AI agent. In addition, FIG. 4 shows a diagram illustrating a configuration for accelerating the collection of a robot learning data set and a robot skill set.

### Method Workflow

The key steps involved in this automated robot design method are as follows:
1. Requirement Acquisition: The process begins with the AI agent acquiring the user's requirements for the customized robot. This can be achieved through various means:

Natural Language Processing: The AI agent can process textual descriptions provided by the user, extracting key information about the desired robot's functionality, size, and other relevant characteristics.

Image and Sketch Analysis: If the user provides images or sketches of the desired robot, the AI agent can analyze these visual inputs to extract design features and preferences.

Interactive Dialogue: The AI agent can engage in an interactive dialogue with the user to clarify requirements, ask further questions, and resolve any ambiguities. This can be done through a conversational interface, where the user can provide feedback and refine their requirements in real-time.
2. Multimodal Data Processing: Once the user's requirements are acquired, the AI agent processes this multimodal data, which may include text, images, and 3D models. The agent utilizes multimodal AI techniques to effectively process and integrate these diverse data types:

Feature Extraction: The AI agent extracts relevant features from each data modality. For example, from text, it might extract keywords related to robot functionality; from images, it could identify shapes and spatial relationships; and from 3D models, it can extract precise geometric information.

Cross-Modal Mapping: The AI agent maps and aligns information across different modalities, for example, associating a textual description of a “gripper” with an image of a robotic gripper or a 3D model of a specific gripper design.

Knowledge Integration: The AI agent integrates the processed information with its existing knowledge base of robotics principles and design constraints. This ensures that the generated designs are not only consistent with the user's requirements but also feasible and practical.
3. Design Generation: Based on the processed user requirements and integrated knowledge, the AI agent generates customized robot designs. This involves several aspects:

Component Selection: The AI agent selects appropriate robot components from a database or knowledge base. This database could contain a wide range of components, such as manipulators, end-effectors, sensors, actuators, and controllers. The selection process considers factors like the robot's intended tasks, workspace limitations, payload requirements, and desired performance characteristics.

Configuration Design: The AI agent determines the optimal configuration of the selected components. This includes aspects like the arrangement of robot links, the placement of sensors and actuators, and the overall robot structure.

Parameter Optimization: The AI agent optimizes design parameters, such as link lengths, joint limits, and control gains, to achieve the desired performance.
4. Design Optimization: After generating an initial design, the AI agent further optimizes it using machine learning techniques and its knowledge base:

Performance Optimization: The AI agent uses machine learning algorithms to optimize the robot design for specific performance metrics, such as speed, accuracy, energy efficiency, or robustness. This could involve training a model on simulated or real-world data to predict the robot's performance and iteratively adjusting design parameters to improve it.

Constraint Satisfaction: The AI agent ensures that the optimized design satisfies all relevant constraints, such as physical limitations, safety regulations, and cost considerations.

Multi-Objective Optimization: The AI agent can perform multi-objective optimization to balance potentially conflicting design goals, such as maximizing performance while minimizing cost.
5. Design Validation: Before the robot is physically constructed, the AI agent validates the optimized design using simulation tools and digital twin technology:

Virtual Prototyping: The AI agent creates a virtual prototype of the designed robot in a simulated environment. This allows the user to visualize the robot's structure and motion, and to assess its suitability for the intended tasks.

Performance Evaluation: The AI agent evaluates the robot's performance in the simulated environment. This can involve running simulations of various tasks and scenarios to assess metrics like speed, accuracy, and stability.

User Feedback: The simulation results and performance metrics are presented to the user for feedback. The user can then provide further input to refine the design or suggest modifications.
6. Robot Construction and Deployment: Once the design is validated and approved by the user, the AI agent assists in the physical construction and deployment of the robot:

Construction Guidance: The AI agent provides detailed specifications, instructions, and 3D models to guide the construction process. This can include information about component assembly, wiring diagrams, and calibration procedures.

Control Code Generation: The AI agent generates control code for the robot, which can be directly deployed to the robot's controller.

System Integration: The AI agent helps integrate the robot with existing automation systems or manufacturing processes, ensuring seamless communication and coordination.

This automated and AI-driven approach to robot design offers significant advantages over traditional methods. It enables rapid design iterations, efficient optimization, and customized solutions tailored to specific user needs, making advanced robotics technology more accessible and facilitating innovation in various application domains.

What is claimed is:

1. A method for automatically designing customized robot using an AI agent, comprising:
acquiring user requirements for a customized robot;
processing the user requirements, including at least two data types selected from textual descriptions, images, and 3D models;
generating a customized robot design based on the processed user requirements;
optimizing the robot design using machine learning techniques and a knowledge base of robotics principles;
validating the optimized robot design using simulation tools; and
assisting in the construction and deployment of the robot.

2. The method of claim 1, wherein acquiring user requirements further comprises interacting with the user through a dialogue interface.

3. The method of claim 1, wherein processing the user requirements further comprises utilizing multimodal AI techniques to integrate and understand the different data types.

4. The method of claim 1, wherein generating a customized robot design further comprises selecting robot components from a database or knowledge base.

5. The method of claim 1, wherein optimizing the robot design further comprises at least one of refining the robot's structure, optimizing component placement, and adjusting control parameters.

6. The method of claim 1, wherein validating the optimized robot design further comprises using digital twin technology to simulate the robot's behavior in a virtual environment.

7. A non-transitory computer-readable recording medium storing instructions that, when executed by a computer, cause a computer to perform the method of claim 1.

8. A system for automatically designing customized robot using an AI agent, comprising:
an AI agent configured to acquire and process user requirements;
a design generation module configured to generate customized robot designs;
a design optimization module configured to optimize the robot designs using machine learning and a knowledge base;
a simulation environment configured to validate the optimized robot designs; and
a robot construction and deployment module configured to assist in the physical realization and deployment of the robot.
